(19) United States
(12) Patent Application Publication
(10) Pub. No.: US 2014/0232240 A1
(43) Pub. Date: Aug. 21, 2014

(54) ELECTROACTIVE POLYMER ENERGY CONVERTER

(71) Applicant: Bayer Intellectual Property GmbH, 40789 Monheim (DE)

(72) Inventors: Roger N. Hitchcock, San Leandro, CA (US); Silmon James Biggs, Los Gatos, CA (US)

(73) Assignee: Bayer Intellectual Property GmbH, Monheim (DE)

(21) Appl. No.: 14/351,637

(22) PCT Filed: Oct. 19, 2012
(86) PCT No.: PCT/US2012/060977

§ 371 Date: Apr. 14, 2014

(30) Foreign Application Priority Data
Oct. 21, 2011 (US) 61549798

(51) Int. Cl. H01L 41/113

(52) U.S. Cl. CPC H01L 41/113
USPC 310/314; 310/331

(57) ABSTRACT

A balanced multi-phase energy conversion apparatus configured to convert energy from a mechanical energy source into electrical energy is disclosed. The energy conversion apparatus may comprise a plurality of transducers. Each of the plurality of transducers comprises a dielectric elastomer module comprising at least one dielectric elastomer film layer disposed between at least first and second electrodes. A transmission coupling mechanism is coupled to the mechanical energy source and operatively attached to the plurality of transducers. The transmission coupling cyclically strains and relaxes the plurality of transducers in response to the mechanical energy acting on the transmission coupling mechanism. The transmission coupling mechanism comprises a work cycle. The plurality of transducers are at evenly distributed points in the work cycle such that a total passive strain energy is constant.

### CROSS REFERENCE TO RELATED APPLICATION

This application claims the benefit, under 35 USC §119(e), of U.S. provisional patent application No. 61/549,798, filed Oct. 21, 2011, entitled “BALANCED MULTI-PHASE GENERATOR FOR DIELECTRIC ELASTOMER GENERATORS.”

### FIELD OF THE INVENTION

The present disclosure relates generally to energy conversion devices. More particularly, the present disclosure relates to electroactive polymer arrays configured in a multi-phase arrangement to convert mechanical energy to electrical energy in an efficient manner.

### BACKGROUND OF THE INVENTION

In general, electroactive polymer energy conversion devices such as generators, for example roll generators, require a high level of reactive mechanical power to produce electrical power. A single electroactive polymer energy generator element may convert only 15% of the mechanical power into electrical power. SRI International of Menlo Park, Calif. is reported to have developed two-phase systems that improve this conversion up to approximately 30%. Such systems, however, cannot adequately obtain overall system efficiency of greater than 80%.

In addition, electroactive polymers generally require high voltage electronics to produce electricity. For some applications simplicity is important but not at the expense of reliability. Simple, high-voltage electrical circuits are generally required to provide functionality and protection. A basic electroactive polymer generator circuit consists of a low voltage priming supply, a connection diode, an electroactive polymer generator, a second connection diode, and a high voltage collector supply. Such a circuit, however, is not effective at capturing as much energy per cycle as may be required by an electroactive polymer generator according to this disclosure and requires a relatively higher voltage priming supply.

Wave and wind energy are renewable resources capable of delivering thousands of megawatt-hours of electricity every year. Harvesting even a small percentage of this energy can provide a significant source of power. New concepts, such as, for example, utilizing electroactive polymer based generators may help solve a number of these challenges.

The present disclosure provides improved energy converters employing electroactive polymers. The present disclosure provides various embodiments of improved electroactive polymer based energy converters in terms of efficiencies, reliabilities, and overall performance vis-à-vis conventional technologies.

### SUMMARY OF THE INVENTION

The present disclosure provides an electroactive polymer based energy conversion device. In one embodiment, an energy conversion apparatus is configured to convert energy from a mechanical energy source into electrical energy. The energy conversion apparatus may comprise a plurality of transducers. Each of the plurality of transducers comprises a dielectric elastomer module comprising at least one dielectric elastomer film layer disposed between at least first and second electrodes. A transmission coupling mechanism is coupled to the mechanical energy source and operatively attached to the plurality of transducers. The transmission coupling cyclically strains and relaxes the plurality of transducers in response to the mechanical energy acting on the transmission coupling mechanism. The transmission coupling mechanism comprises a work cycle. The plurality of transducers are at evenly distributed points in the work cycle such that a total passive strain energy is constant.

These and other advantages and benefits of the present invention will be apparent from the Detailed Description of the Invention herein below.

### BRIEF DESCRIPTION OF THE FIGURES

The present invention will now be described for purposes of illustration and not limitation in conjunction with the figures, wherein:

FIG. 1 is a block diagram of an energy conversion device that may be used for harvesting electricity from a mechanical energy source,

FIG. 2 illustrates a cycle for converting energy using an energy conversion device including an electroactive polymer film of some type,

FIG. 3A illustrates a top perspective view of a transducer portion in accordance with one embodiment,

FIG. 3B illustrates a top perspective view of the transducer portion including deflection in response to a change in electric field,

FIGS. 4A-4F illustrate one cycle of an electroactive polymer generator for converting mechanical energy using an energy conversion device including an electroactive polymer film, e.g., a dielectric elastomer film,

FIG. 5 illustrates one embodiment of a simple power generation circuit,

FIG. 6 is a graphical representation of energy versus stretch ratio of a constant charge cycle in an electroactive polymer generator,

FIG. 7 is a block diagram of one embodiment of electroactive polymer generator energy harvesting control system utilizing microcontroller electronics,

FIG. 8 is a block diagram of one embodiment of a high efficiency energy transfer circuit for an electroactive polymer generator,

FIG. 9 illustrates one embodiment of a balanced multi-phase generator comprising a first and second swashplate.

FIGS. 10A-10B illustrate one embodiment of a balanced multi-phase generator comprising a first transducer and a second transducer.

FIG. 11 is a free body diagram of a transmission coupling mechanism of a balanced multi-phase generator.

FIG. 12 is a free body diagram of a transmission coupling mechanism of a balanced multi-phase generator having an off-set swashplate.

FIG. 13 illustrates one embodiment of a balanced multi-phase generator comprising six transducer elements.

FIG. 14 illustrates one embodiment of a balanced multi-phase generator comprising a sinusoidal cam.

### DETAILED DESCRIPTION OF THE INVENTION

Before explaining the embodiments of electroactive polymer based energy conversion devices and electroactive polymer based arrays configured to convert mechanical energy to electrical energy, it should be noted that the disclosed embodiments are not limited in application or use to the details of construction and arrangement of parts illustrated in the accompanying drawings and description. The disclosed embodiments may be implemented or incorporated in other embodiments, variations and modifications, and may be practiced or carried out in various ways. Further, unless otherwise indicated, the terms and expressions employed herein have been chosen for the purpose of describing the embodiments for illustrative purposes and for the convenience of the reader and are not intended for the purposes of limiting any of the embodiments to the particular ones disclosed. Further, it should be understood that any one or more of the disclosed embodiments, expressions of embodiments, and examples can be combined with any one or more of the other disclosed embodiments, expressions of embodiments, and examples, without limitation. Thus, the combination of an element disclosed in one embodiment and an element disclosed in another embodiment is considered to be within the scope of the present disclosure and appended claims.

In various embodiments, the present disclosure provides electroactive polymer based energy conversion devices that may be used to convert electrical energy and mechanical energy in a bi-directional manner. It will be appreciated that the terms “electroactive polymer,” “dielectric elastomer,” and/or “elastomeric dielectric element,” may be used interchangeably throughout the present disclosure. In one embodiment, the present disclosure provides generators with one or more transducers that employ electroactive polymer films configured to convert mechanical energy to electrical energy. In another embodiment, the present disclosure provides arrays of transducers employing electroactive polymer films configured in a multi-phase arrangement to convert mechanical energy to electrical energy in an efficient manner. Still in other embodiments, the present disclosure provides energy transfer and energy harvesting circuits and techniques for transducers employing electroactive polymer film arrays configured to convert mechanical energy to electrical energy. These and other specific embodiments are illustrated and described herein below.

This present application is related to the subject matter of PCT patent application number PCT/US12/28406, filed on Mar. 9, 2012, entitled “ELECTROACTIVE POLYMER ENERGY CONVERTER”, the entire contents of which is incorporated by reference and provides various embodiments of generators with one or more transducers that employ electroactive polymer films to convert mechanical energy to electrical energy and electrical circuit techniques for more efficiently converting the mechanical energy into electrical energy. In one embodiment, a generator module comprises electroactive polymer transducers comprising integrated dielectric elastomer elements, available from Artificial Muscle, Inc. (AMI) of Sunnyvale, Calif. Such generators may be referred to herein as electroactive polymer generator modules. Such electroactive polymer generator modules have characteristics suitable for implementing energy conversion techniques, including, for example, mechanical-to-electrical energy conversion. Such electroactive polymer generator modules comprise a stretchable resilient material with a dielectric elastomer film sandwiched between two electrode layers. The application of a mechanical force to strain (stretch) an electroactive polymer generator module changes the capacitance of the dielectric elastomer film between the electrodes. A seed charge applied to the strained film rises to a higher film voltage, which can be harvested when the electroactive polymer generator module relaxes. The electroactive polymer generator modules are suitable for direct drive applications, are highly scalable, reliable, and efficient.

In addition to providing various embodiments of electroactive polymer generators, the present disclosure also provides conditioning electronics logic and circuits and techniques that may be employed in conjunction with electroactive polymer generator modules to increase the efficiency of the generator. Each of these techniques will be described separately herein below.

The generators may comprise one or more transmission mechanisms that couple to a source of mechanical energy and convert a portion of the mechanical energy to drive the one or more transducer portions of the generator. The transducers convert the mechanical energy to electrical energy in conjunction with conditioning electronics electrically to the generator. Common sources of mechanical energy include, for example, water at rest or in motion, tides, waves, wind, solar, geothermal, among others.

The fundamental mechanism for generating electrical power from mechanical power utilizing electroactive polymers is the change in capacitance that the dielectric elastomer undergoes while cyclically stretching and contracting in response to the mechanical power. To be a significant electrical power generator an electroactive polymer generator should undergo at least a 3× to 4× capacitance change from a relaxed contracted state to a stretched state. Factors that contribute to the performance, efficiency, and reliability of a suitable electroactive polymer generator include dielectric materials, electrodes, mechanical configuration, electronics, and energy density and efficiency.

### Electroactive Polymer Energy Conversion Device

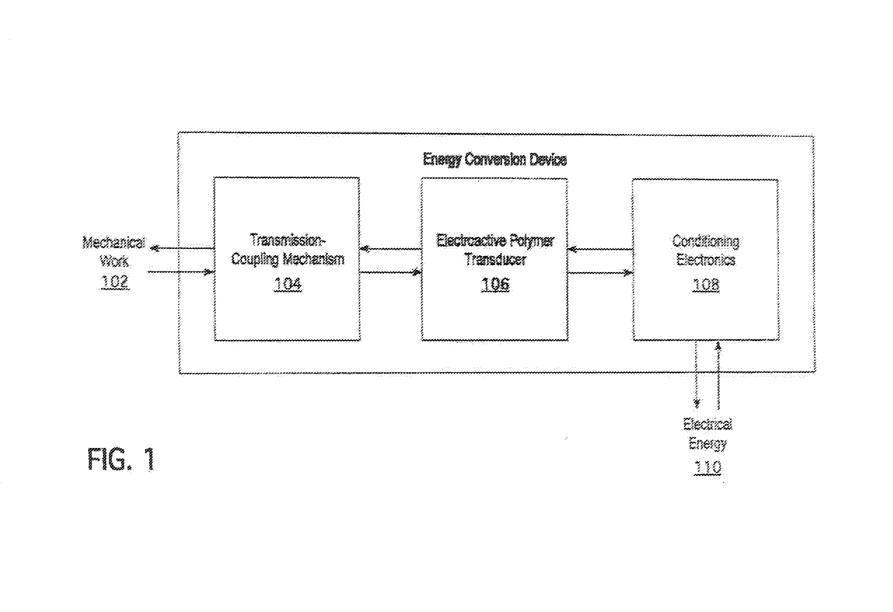

FIG. 1 is a block diagram of an energy conversion device 100 (generator 100) that may be used for harvesting electricity from a mechanical energy source 102. The mechanical energy source 102 may be input into the generator 100 in some manner via one or more transmission coupling mechanisms 104. Then, the mechanical energy may be converted to electrical energy by one or more transducers employing an electroactive polymer 106 in conjunction with conditioning electronics 108. Also, a portion of the mechanical energy may be used to perform additional mechanical work. The conditioning electronics 108 may transfer harvested electrical energy 110 to an electrical energy output. In some embodiments, the generator 100 may be operated in reverse to perform mechanical work upon the application of electrical power to the electroactive polymer transducers 106.

The mechanical energy used to generate electricity may be provided from a number of sources. For instance, the mechanical energy source 102 may be harvested from environmental sources such as water at rest or in motion, tides, waves, wind, solar, geothermal, among other sources. The environmental energy source may be transferred to the transducers 106 by a working fluid such water or air to generate mechanical work or energy. The mechanical energy may be harvested using the one or more electroactive polymer transducers 106 of the present disclosure to convert into electricity 110. A choice of the working fluid as well as other components of the generator 100 may depend on one or more operational and design parameters of the generator 100 such as operational environment of the generator (e.g., commercial, residential, land, marine, portable, non-portable, etc.), size of the generator, cost requirements, durability requirements, efficiency requirements, temperature of the power source and power output requirements.

In one embodiment, the mechanical energy to drive the generator 100 may be derived from water at rest or in motion, as in a hydroelectric plant that taps into mechanical energy and converts it into electrical energy. The primary components of such a mechanical energy source 102 would include a dam, a reservoir, a penstock, a transmission coupling mechanism 104, one or more electroactive polymer transducers 106, conditioning electronics 108, a transformer, and pipelines. A dam is a system that efficiently harnesses the mechanical energy, both potential and kinetic, of water. It can be built over a body of water, such as a river, with a natural elevation. The mechanical energy also may be derived from moving water such as that used to mill grain.

In another embodiment, the mechanical energy to drive the generator 100 may be derived from tides. The tides of the ocean produce two different types of energies, including thermal energy, or from the heat of the sun, and mechanical energy, by the motion of the waves and tides. The mechanical energy is exploited from the movement of the tides. The components of a tidal mechanical energy source 102 would include a mechanism to capture the mechanical energy, a transmission coupling mechanism 104, one or more electroactive polymer transducers 106, and conditioning electronics 108 to convert the mechanical energy into electricity. This may be done by using buoys, energy barrages, and water mills, for example.

Windmills and wind turbines use renewable wind energy to produce mechanical energy. A windmill works on the principle of converting kinetic energy, generated by the rotation of its blades, into rotational mechanical energy. A transmission coupling mechanism 104 couples the rotational mechanical energy to the one or more electroactive polymer transducers 106 and conditioning electronics 108 to convert the mechanical energy into electricity. Windmills are commonly installed in mountainous and coastal areas, where the wind speeds range from 5 to 15.5 miles per hour. The generator 100 according to the present disclosure harnesses the power of the wind to produce electricity using the one or more electroactive polymer transducers 106 and conditioning electronics 108. There are two types of wind turbines, including vertical axis wind turbines and horizontal axis wind turbines.

It will be appreciated that the above description of example mechanical energy sources is not exhaustive and other sources such as thermal energy sources may be employed to drive the one or more electroactive polymer transducers 106 and conditioning electronics 108 to generate electricity. Thermal energy can be generated from a variety of heat sources such as solar energy, geothermal energy, internal combustion, external combustion, or waste heat. The thermal energy can be converted to mechanical energy such that it can be used to drive the one or more transducers 106 located in the generator 100.

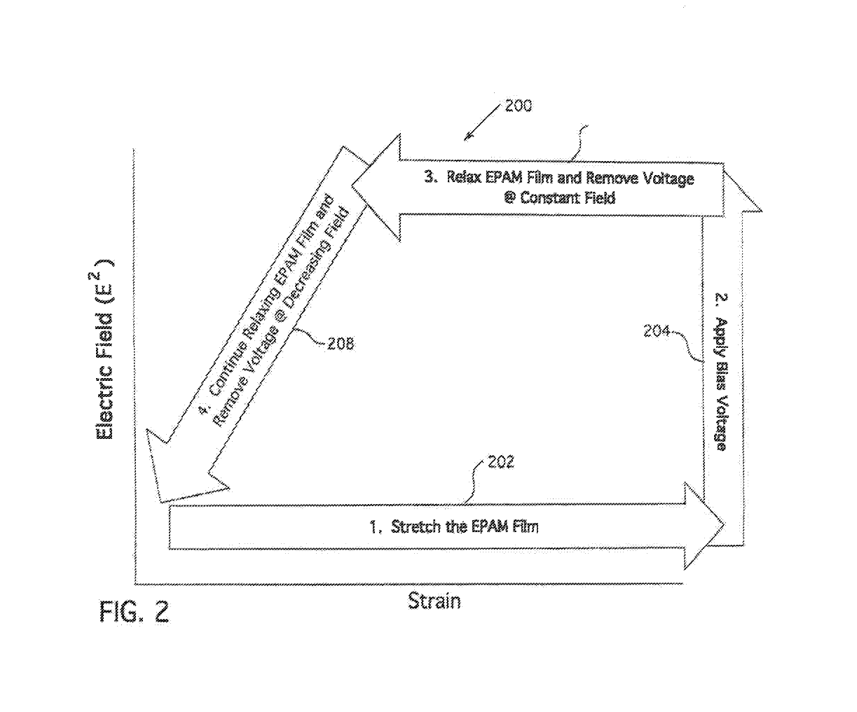

FIG. 2 illustrates a cycle 200 for converting energy using an energy conversion device including an electroactive polymer film of some type. The vertical axis depicts Electric Field, proportional to E² and the horizontal axis depicts strain. When the energy conversion device is operated as a mechanical-to-electric generator, mechanical energy is converted to electricity. In general, the mechanical energy source is used to deflect or stretch the electroactive polymer film in some manner. An energy conversion device of the present disclosure also may be used to perform mechanical work. In this case, electrical energy may be used to deflect an electroactive polymer film. Mechanical work performed by the electroactive polymer film in the deflection process may be used to apply a mechanical process. To generate electrical energy over an extended time period or to perform thermal work, the electroactive polymer film may be stretched and relaxed over many cycles.

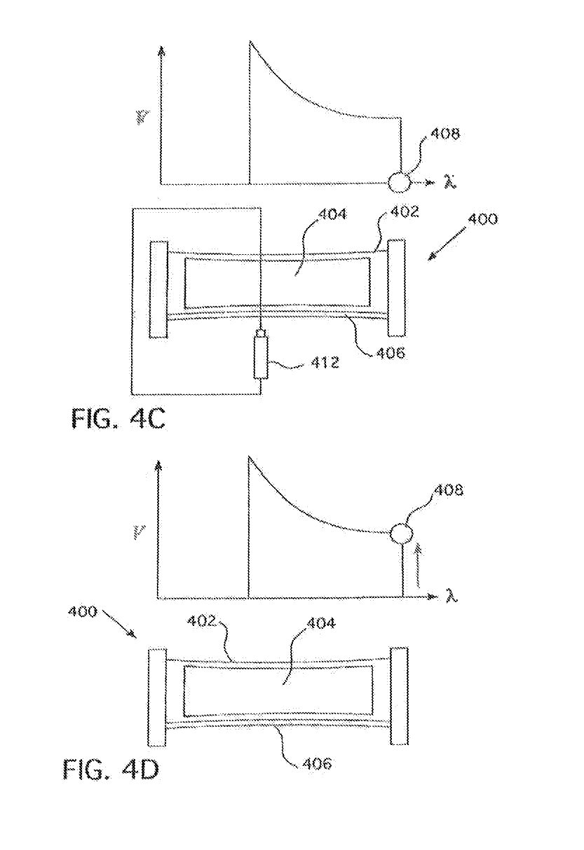

In FIG. 2, one cycle 200 of an electroactive polymer film stretching and relaxing to convert mechanical energy to electrical energy is shown. The cycle is for illustrative purposes only. Many different types of cycles may be employed by energy conversion devices of the present disclosure and the energy conversion devices are not limited to the cycle shown in FIG. 2. In 202, the electroactive polymer film is stretched with zero electric field pressure on the polymer. This stretching may result from a mechanical force applied to the film generated from an external energy source input into the energy conversion device. For example, a mechanical process may be used to deflect the electroactive film. In 204, the electric field pressure on the polymer film is increased to some maximum value. Conditioning electronics necessary to perform this function are described with reference to FIGS. 5, 7, and 8. In this example, the maximum value of the electric field pressure is just below the electrical breakdown strength of the electroactive polymer. The breakdown strength may change with time at a rate that may depend on but is not limited to: 1) an environment in which an energy conversion device is used, 2) an operational history of the energy conversion device, and 3) a type of polymer used in the energy conversion device.

In 206, the electroactive polymer relaxes while the electric field pressure is maintained near its maximum value. The relaxation process may correspond to elastic restoring properties of the electroactive polymer allowing the electroactive film to relax. As the electroactive polymer relaxes, the voltage of the charge on the electroactive polymer film is increased. The increase in charge's electrical energy, as indicated by its higher voltage, on the electroactive polymer film is harvested to generate electrical energy. In 208, the electroactive polymer film fully relaxes as the electric field pressure is reduced to zero and the cycle may be repeated. For instance, the cycle may be initiated when a rotational mechanical force and cam mechanism is used to stretch and relax the electroactive polymer film.

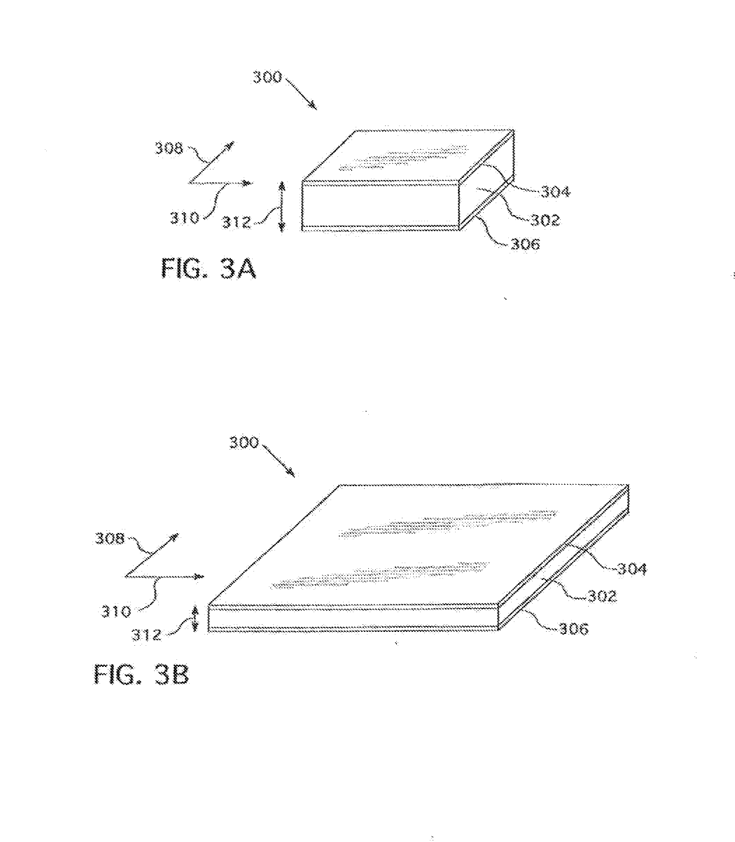

The transformation between electrical and mechanical energy in devices of the present disclosure is based on energy conversion by one or more active areas of an electroactive polymer, such as for example, an electroactive polymer dielectric elastomer. Electroactive polymers deflect when actuated by electrical energy. To help illustrate the performance of an electroactive polymer in converting electrical energy to mechanical energy, FIG. 3A illustrates a top perspective view of a transducer portion 300 in accordance with one embodiment. The transducer portion 300 comprises an electroactive polymer 302 for converting between electrical energy and mechanical energy. In one embodiment, an electroactive polymer refers to a polymer that acts as an insulating dielectric between two electrodes and may deflect upon application of a voltage difference between the two electrodes. Top and bottom electrodes 304 and 306 are attached to the electroactive polymer 302 on its top and bottom surfaces, respectively, to provide a voltage difference across a portion of the polymer 302. The polymer 302 deflects with a change in electric field provided by the top and bottom electrodes 304 and 306. Deflection of the transducer portion 300 in response to a change in electric field provided by the electrodes 304 and 306 is referred to as actuation. As the polymer 302 changes in size, the deflection may be used to produce mechanical work.

FIG. 3B illustrates a top perspective view of the transducer portion 300 including deflection in response to a change in electric field. In general, deflection refers to any displacement, expansion, contraction, torsion, linear or area strain, or any other deformation of a portion of the polymer 302. The change in electric field corresponding to the voltage difference applied to or by the electrodes 304 and 306 produces mechanical pressure within the polymer 302. In this case, the unlike electrical charges produced by the electrodes 304 and 306 attract each other and provide a compressive force between the electrodes 304 and 306 and an expansion force on the polymer 302 in the planar directions 308, 310, causing the polymer 302 to compress between the electrodes 304, 306 and stretch in the planar directions 308, 310.

In some cases, the electrodes 304 and 306 cover a limited portion of the polymer 302 relative to the total area of the polymer. This may be done to prevent electrical breakdown around the edge of the polymer 302 or to achieve customized deflections for one or more portions of the polymer. As the term is used herein, an active area is defined as a portion of a transducer comprising the polymer material 302 and at least two electrodes. When the active area is used to convert electrical energy to mechanical energy, the active area includes a portion of the polymer 302 having sufficient electrostatic force to enable deflection of the portion. When the active area is used to convert mechanical energy to electrical energy, the active area includes a portion of the polymer 302 having sufficient deflection to enable a change in electrostatic energy. As will be described below, a polymer of the present invention may have multiple active areas. In some cases, polymer 302 material outside an active area may act as an external spring force on the active area during deflection. More specifically, polymer material outside the active area may resist active area deflection by its contraction or expansion. Removal of the voltage difference and the induced charge causes the reverse effects.

The electrodes 304 and 306 are compliant and change shape with the polymer 302. The configuration of the polymer 302 and the electrodes 304 and 306 provides for increasing the polymer 302 response with deflection. More specifically, as the transducer portion 300 deflects, compression of the polymer 302 brings the opposite charges of electrodes 304 and 306 closer and the stretching of the polymer 302 separates similar charges in each electrode. In one embodiment, one of the electrodes 304 and 306 is ground.

In general, the transducer portion 300 continues to deflect until mechanical forces balance the electrostatic forces driving the deflection. The mechanical forces include elastic restoring forces of the polymer 302 material, the compliance of electrodes 304 and 306 and any external resistance provided by a device and/or load coupled to the transducer portion 300. The deflection of the transducer portion 300 as a result of the applied voltage may also depend on a number of other factors such as the polymer 302 dielectric constant and the thickness of the polymer 302.

Electroactive polymers in accordance with the present disclosure are capable of deflection in any direction. After application of the voltage between electrodes 304 and 306, the polymer 302 expands (stretches) in both of the planar directions 308 and 310. In some cases, the polymer 302 is incompressible, e.g. has a substantially constant volume under stress. For an incompressible polymer 302, the polymer 302 decreases in thickness as a result of the expansion in the planar directions 308 and 310. It should be noted that the present invention is not limited to incompressible polymers and deflection of the polymer 302 may not conform to such a simple relationship.

Application of a relatively large voltage difference between the electrodes 304 and 306 on the transducer portion 300 shown in FIG. 3A will cause the transducer portion 300 to change to a thinner, larger area shape as shown in FIG. 3B. In this manner, the transducer portion 300 converts electrical energy to mechanical energy. The transducer portion 300 also may be used to convert mechanical energy to electrical energy in a bi-directional manner.

FIGS. 3A and 3B may be used to show one manner in which the transducer portion 300 converts mechanical energy to electrical energy. For example, if the transducer portion 300 is mechanically stretched by external forces to a thinner, larger area shape such as that shown in FIG. 3B, and a relatively small voltage difference (less than that necessary to actuate the film to the configuration in FIG. 3B) is applied between the electrodes 304, 306, the transducer portion 300 will contract in area between the electrodes to a shape such as in FIG. 3A when the external forces are removed. Stretching the transducer refers to deflecting the transducer 300 from its original resting position—typically to result in a larger net area between the electrodes, e.g., in the plane defined by the directions 308, 310 between the electrodes. The resting position refers to the position of the transducer portion 300 having no external electrical or mechanical input and may comprise any pre-strain in the polymer. Once the transducer portion 300 is stretched, a relatively small voltage difference is provided such that the resulting electrostatic forces are insufficient to balance the elastic restoring forces of the stretch. The transducer portion 300 therefore contracts, and it becomes thicker and has a smaller planar area in the plane defined by the directions 308, 310 (orthogonal to the thickness between electrodes in the direction 312). When the polymer 302 becomes thicker, it separates electrodes 304, 306 and their corresponding unlike charges, thus raising the electrical energy and voltage of the charge. Further, when the electrodes 304, 306 contract to a smaller area, the density of like charges within each electrode increases, raising the electrical energy and voltage of the charge. Thus, with different charges on the electrodes 304, 306, contraction from a shape such as that shown in FIG. 3B to one such as that shown in FIG. 3A raises the electrical energy of the charge. That is, mechanical deflection is being turned into electrical energy and the transducer portion 300 is acting as a generator.

In some cases, the transducer portion 300 may be described electrically as a variable capacitor. The capacitance decreases for the shape change going from that shown in FIG. 3B to that shown in FIG. 3A. Typically, the voltage difference between the electrodes 304, 306 will be raised by contraction. This is normally the case, for example, if additional charge is not added or subtracted from the electrodes 304, 306 during the contraction process. The increase in electrical energy, U, may be illustrated by the formula U=0.5 Q²/C, where Q is the amount of positive charge on the positive electrode and C is the variable capacitance which relates to the intrinsic dielectric properties of the polymer 302 and its geometry. If Q is fixed and C decreases, then the electrical energy U increases. The increase in electrical energy and voltage can be recovered or used in a suitable device or electronic circuit in electrical communication with the electrodes 304, 306. In addition, the transducer portion 300 may be mechanically coupled to a mechanical input that deflects the polymer and provides mechanical energy.

The transducer portion 300 will convert mechanical energy to electrical energy when it contracts. Some or all of the charge and energy can be removed when the transducer portion 300 is fully contracted in the plane defined by the directions 308, 310. Alternatively, some or all of the charge and energy can be removed during contraction. If the electric field pressure in the polymer 302 increases and reaches balance with the mechanical elastic restoring forces and external load during contraction, the contraction will stop before full contraction, and no further elastic mechanical energy will be converted to electrical energy. Removing some of the charge and stored electrical energy reduces the electrical field pressure, thereby allowing contraction to continue. Thus, removing some of the charge may further convert mechanical energy to electrical energy. The exact electrical behavior of the transducer portion 300 when operating as a generator depends on any electrical and mechanical loading as well as the intrinsic properties of the polymer 302 and electrodes 304, 306.

In one embodiment, the electroactive polymer 302 may be pre-strained. Pre-strain of a polymer may be described, in one or more directions, as the change in dimension in a direction after pre-straining relative to the dimension in that direction before pre-straining. The pre-strain may comprise elastic deformation of the polymer 302 and be formed, for example, by stretching the polymer in tension and fixing one or more of the edges while stretched. For many polymers, pre-strain improves conversion between electrical and mechanical energy. The improved mechanical response enables greater mechanical work for an electroactive polymer, e.g., larger deflections and actuation pressures. In one embodiment, pre-strain improves the dielectric strength of the polymer 302. In another embodiment, the pre-strain is elastic. After actuation, an elastically pre-strained polymer could, in principle, be unfixed and return to its original state. The pre-strain may be imposed at the boundaries using a rigid frame or may also be implemented locally for a portion of the polymer.

In one embodiment, pre-strain may be applied uniformly over a portion of the polymer 302 to produce an isotropic pre-strained polymer. By way of example, an acrylic elastomeric polymer may be stretched by 200 to 400 percent in both planar directions. In another embodiment, pre-strain is applied unequally in different directions for a portion of polymer 302 to produce an anisotropic pre-strained polymer. For example, a silicone film may be stretched by 0 to 10% in one planar direction and 10 to 100% in the other planar direction. In this case, the polymer 302 may deflect greater in one direction than another when actuated. While not wishing to be bound by theory, the present inventors speculate that pre-straining a polymer in one direction may increase the stiffness of the polymer in the pre-strain direction. Correspondingly, the polymer is relatively stiffer in the high pre-strain direction and more compliant in the low pre-strain direction and, upon actuation, more deflection occurs in the low pre-strain direction. In one embodiment, the deflection in the direction 308 of the transducer portion 300 can be enhanced by exploiting large pre-strain in the perpendicular direction 310. For example, an acrylic elastomeric polymer used as the transducer portion 300 may be stretched by 300 percent in the direction 308 and by 500 percent in the perpendicular direction 310. The quantity of pre-strain for a polymer may be based on the polymer material and the desired performance of the polymer in an application.

Anisotropic pre-strain also may improve the performance of the transducer 300 to convert mechanical energy to electrical energy in a generator mode. In addition to increasing the dielectric breakdown strength of the polymer and allowing more charge to be placed on the polymer, high pre-strain may improve mechanical to electrical coupling in the low pre-strain direction. That is, more of the mechanical input into the low pre-strain direction can be converted to electrical output, thus raising the efficiency of the generator.

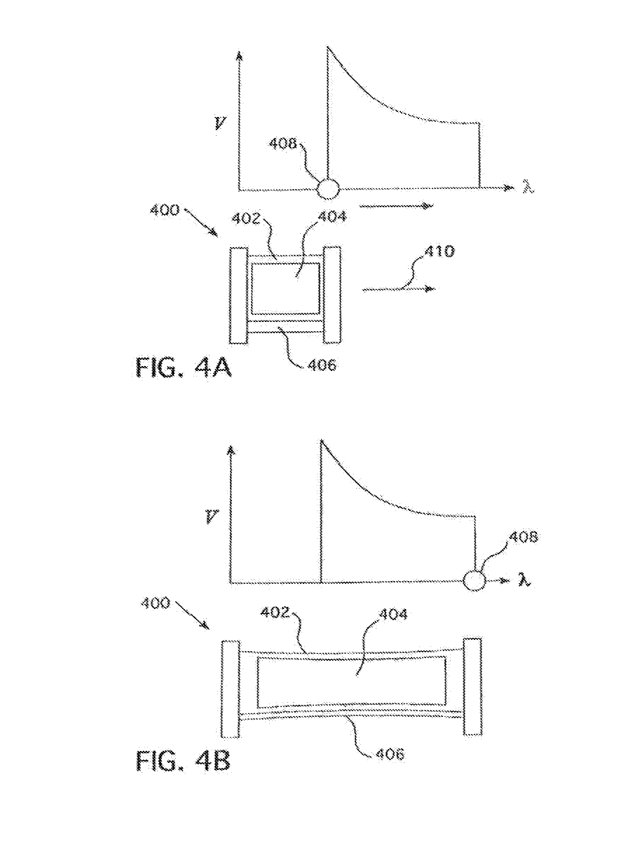

FIGS. 4A-4F illustrate one cycle of an electroactive polymer generator 400 for converting mechanical energy using an energy conversion device including an electroactive polymer film 402, e.g., a dielectric elastomer film. A graphical representation accompanies the illustrative cycle, where the vertical axis corresponds to Electric Field (Voltage) and the horizontal axis corresponds to Strain Ratio (λ) to illustrate the mechanical to electrical power conversion cycle. Stretchable electrodes 404, 406 are formed on the electroactive polymer film 402. When the dielectric elastomer film 402 is relaxed, the electric charge 408 stored by the electroactive polymer film 402 is at a first level. The electroactive polymer film 402 and the stretchable electrodes 404, 406 are then stretched in the direction 410 by any suitable mechanical work. The electric charge 408 remains at the first level. As shown in FIG. 4B, the electroactive polymer generator 400 is in a stretched state. The electroactive polymer film 402 and the stretchable electrodes 404, 406 change capacitance when stretched. In one aspect, in the stretched state, the stretchable electrodes 404, 406 are closer together and raise the capacitance. When the electroactive polymer film 402 and the stretchable electrodes 404, 406 are in a stretched state, as shown in FIG. 4C, the electrodes 404, 406 are coupled to an energy source 412, e.g., a direct current (DC) battery, and a bias voltage is applied to the electroactive polymer film 402 to raise the charge 408 to a higher voltage. As shown in FIG. 4D, the energy source is removed and the electroactive polymer film 402 remains charged at the higher voltage. As shown in FIG. 4E, as the electroactive polymer film 402 and the stretchable electrodes 404, 406 are relaxed in the direction 414, the electroactive polymer film 402 and the stretchable electrodes 404, 406 shrink and separate. Accordingly, the capacitance of the electroactive polymer film 402 is lowered and the voltage is raised to a higher level. As shown in FIG. 4F, when the electroactive polymer film 402 and the stretchable electrodes 404, 406 are back is a relaxed state, the electrodes 404, 406 are coupled to a load 416 and the stored voltage (or charge) is delivered to the load 416, thus discharging the electroactive polymer film 402. The cycles repeat in accordance with the mechanical work applied at the input of the electroactive polymer generator 400.

With reference now to FIGS. 4A-4F, whether the electroactive polymer film 402 is being used as an actuator or a electroactive polymer generator 400, the basic structure of the electroactive polymer film 402 is high dielectric elastomeric film patterned on each side with stretchable electrodes 404, 406. In actuator mode, when a voltage is applied to the electroactive polymer 402, the polymer compresses in thickness and expands in area by the effect of the electrostatic forces from the unlike charges on the two electrodes 404, 406. Generator mode is basically the reverse of the actuator mode. Application of mechanical energy 410 to the electroactive polymer film 402 to stretch it causes compression in thickness and expansion of the surface area. At this point, a voltage 412 is applied to the electroactive polymer film 402. The applied electrical energy 412 is stored on the polymer 402 as electric charge 408. When the mechanical energy decreases 414, the elastic recovery force of the electroactive polymer film 402 acts to restore the original thickness and to decrease the area. This mechanical change increases the voltage potential between the two electrodes 404, 406 layers, resulting in an increase of electrostatic energy.

### Energy Density of the Electroactive Polymer Generator

An energy density of 0.4 joules per gram (per actuation cycle) has been demonstrated for an electroactive polymer generator 400 with an acrylic based electroactive polymer film 402 material. Achieving the energy density of 0.4 joules per gram requires the use of conditioning electronics to optimize the complete generation cycle of an electroactive polymer power generator 400. In one embodiment, microcontroller based electronics and logic may be employed. At power levels greater than 100 watts, conditioning electronics circuits enable the advantages of the electroactive polymer generator 400 to be exploited.

Unlike electromagnetic generators, electroactive polymer generators 400 scale linearly with power. For example, to create a generator ten times more powerful at least ten times more material is required. This is not the case with electromagnetic generators. Electromagnetic generators have two important advantages as they scale up in power. First, their weight and volume do not scale linearly. The mass of a 10 kilowatt generator will only be approximately three times the mass of a 1 kilowatt generator. As indicated, by the time the electroactive polymer generator 400 is on the order of 100 kilowatts, the power density has improved by an order of magnitude, making it very competitive at higher powers. Secondly, as electromagnetic generators increase in power, their efficiencies improve. Many high power generators have efficiencies exceeding 97%.

Electroactive polymer generators 400 provide advantages over electromagnetic generators when the following criteria are met:

Electroactive polymer generators 400 provide advantages when forces are high and velocities are low. Mechanical power equals force multiplied by velocity. Electromagnetic generators are well suited for high velocity mechanical power (especially rotational). Rotational speeds of 1800 RPM (30 rotations per second) are typically used for standard utility power (60 hertz in the US, 50 hertz in Europe and other places). For a typical three horsepower (2238 watts) electromagnetic generator, the rotor surface speed would be approximately 15-20 meters per second. In comparison, a one meter high ocean wave at 0.3 hertz only achieves a maximum speed of 0.9 meters per second but can generate very high forces. Wind power is also typically slow. Many wind turbines rotate at about 30 RPM and require gear boxes to increase this by a factor of 50 (to achieve 1500 rpm) to connect to the electromagnetic generator. Suitable electroactive polymer generators 400 may be directly coupled to the main shaft of a wind turbine to produce electrical power.

In addition, electroactive polymer generators 400 provide an advantage when connected to a regulated high voltage DC electrical grid in the range of 2-10 kVdc. Because of the way electroactive polymer generators 400 generate electrical power they are well suited for high voltage DC systems. Rotational electromagnetic generators typically generate at voltages less than 600 volts and produce alternating current waveforms. To convert this to high voltage DC either a transformer/rectifier set must be used or some other type of high power inverter electronics. Electroactive polymer generators 400 can be directly connected to a high voltage dc grid with a minimum of electronics. The corollary side of this is that electroactive polymer generators 400 require conversion electronics to convert the high voltage DC power into low voltage power suited for most low power electronics type applications.

Furthermore, electroactive polymer generators 400 that are self-starting provide an advantage at remote locations when standard utility power is not available. Competing technologies for this criterion are solar power, wind power with electromagnetic generators and hydro-power with electromagnetic generators. Two of these (wind and solar) share an even further complexity in that these sources of power are not predictable. Therefore, either the system must be self starting or a sufficient amount of electrical storage (typically batteries) must be included to handle periods of unavailability.

In the general case of power generation, reliability is one of the most important aspects. Electromagnetic power generation has been utilized for over 100 years. During that time, electromagnetic generators have demonstrated reliability exceeding 30 years of useful life. In addition, electromagnetic generators have been built in power ranges from milliwatts to megawatts.

For wind power applications, an electroactive polymer generator 400 must be able to handle environmental conditions associated with the application. Temperature and humidity requirements vary by location (for example: the wind generators located at the Altamont Pass in Central California experience less variation in temperature then those located in Denmark). Basic protection from the elements is assumed and will be in the form of rain protected enclosures however additional precautions will be required for electroactive polymer generators 400 and the associated electronics due to the nature of high voltage DC. Many high voltage electronic systems require periodic maintenance to remove accumulated dust attracted to high voltage parts. Either a sealed enclosure is necessary or some other measures must be made to prevent the buildup of unwanted particles (high voltage dc conductors basically act as electrostatic precipitators and collect dust and other airborne particles).

### Dielectric and Electrode Materials

It will be appreciated that a plurality of composite materials can be used to implement the electroactive active polymer transducers. For the composite material to be used as mechanical-to-electrical energy transducers, the composite material must move, and in order to move, the soft but incompressible dielectric layers must have somewhere to go. Accordingly, such composite materials should comprise at least the following three types of materials: (1) Hard—rigid structural layers that carry loads and match the stiffness of the electrical and mechanical elements to which the transducer interfaces; (2) Soft—low modulus, incompressible dielectric elastomer layers that can be deformed by mechanical loads coming from outside the composite material and by internal electric fields applied to control the composite; and (3) Compressible—regions of gas, liquid or expanded porous materials (e.g., foams or aerogels), for example, into which the dielectric elastomer may bulge. These and other composite materials may be found in U.S. Provisional Patent Application Ser. No. 61/545,295, filed Oct. 10, 2011, entitled “COMPOSITE ELECTRODES COMPRISED OF A TEXTURED, RIGID, INSULATOR COVERED WITH THIN, SELF-HEALING CONDUCTOR LAYERS, AND DIELECTRIC ELASTOMER TRANSDUCERS INCORPORATING SUCH ELECTRODES,” the disclosure of which is incorporated herein by reference in its entirety.

### Electronics for Electroactive Polymer Generators

It is to be appreciated that the embodiments described herein illustrate example implementations, and that the functional elements, logical blocks, program modules, and circuits elements may be implemented in various other ways which are consistent with the described embodiments. Furthermore, the operations performed by such functional elements, logical blocks, program modules, and circuits elements may be combined and/or separated for a given implementation and may be performed by a greater number or fewer number of components or program modules. As will be apparent to those of skill in the art upon reading the present disclosure, each of the individual embodiments described and illustrated herein has discrete components and features which may be readily separated from or combined with the features of any of the other several embodiments without departing from the scope of the present disclosure. Any recited method can be carried out in the order of events recited or in any other order which is logically possible.

Electronics for electroactive polymer generators range from fairly simple to fairly complex. To achieve optimal performance from an electroactive polymer generator requires sophisticated electronics; however modest performance can be achieved using very simple circuit topologies. In addition, application specific details may drive the choice of electronics and their complexity. Applications can range from fixed stroke and fixed frequency in some cases to variable stroke and variable frequency in others. These parameters and other considerations will determine which type of electronics is best suited for a specific application.

Electronics for electroactive polymer power generators can be classified into two groups, control level electronics and power level electronics. Control level electronics are technically feasible and only need to be evaluated from a cost and power consumption point of view. Power level electronics are feasible but keeping the cost low and the efficiency high is a significant trade-off for achieving an optimized design.

FIG. 5 illustrates one embodiment of a simple power generation circuit 800. The advantage of the circuit 800 is its simplicity. Only a small starting voltage 806 (of approximately 9 volts) is necessary to get the generator started (provided mechanical power is being put in). No control level electronics are necessary to control the transfer of high voltage into and out of the electroactive generator 802 via respective high voltage diodes D1 (808) and D2 (810). A passive voltage regulation is achieved by the zener diode 804 on the output of the circuit 800. The circuit 800 is capable of producing high voltage DC power and will operate the electroactive polymer generator 802 at an energy density level around 0.04-0.06 joules per gram. The circuit 800 is suitable for generating modest powers and demonstrating that electroactive polymer generators 802 are technically feasible.

In one embodiment, the circuit 800 utilizes a charge transfer technique to maximize the energy transfer per mechanical cycle of the electroactive polymer generator 802, while still maintaining simplicity. The circuit 800 also enables self priming with extremely low voltages 806 (9 volts, for example). The circuit 800 also enables both variable frequency and variable stroke operation. In various embodiments, the circuit 800 maximizes energy transfer per cycle with simplified electronics (i.e., electronics that do not require control sequences, operates both in variable frequency and variable stroke applications, and provides a simple overvoltage protection to generator element.

To achieve higher power levels and higher energy densities in electroactive polymer generators both the control level electronics and the power electronics require a much higher level of sophistication. These electronics will also be different depending on the type of generator application. Fixed stroke, narrow frequency applications (perhaps water mills) require the least sophistication of the electronics, while variable stroke, variable frequency applications will require the most sophistication. To address the most sophisticated case, the control level electronics have the ability to sense the instantaneous capacitance of each electroactive polymer generator and determine whether it is increasing or decreasing. The electronics decide whether to put charge on the electroactive polymer film, remove charge from the electroactive polymer film, or to simply do nothing.

This would be the case for wave power generation as an example. For times of light wave or no wave activity, the generator should be is a low power, non generating mode (typically called SLEEP mode in electronics). Once a threshold of wave activity is detected, the system should bring the generator online (WAKE UP) and start producing power. If the wave activity falls below a certain level, then the electroactive generator would shut down again waiting for the next period of wave activity. The specific decision making criteria will depend on each application, however a control level electronics of this sophistication will be useful in practically all generator applications (i.e., only a few control level designs should be necessary to cover a wide variety of generator applications).

The power level electronics will be driven by the maximum output power of the electroactive generator. Similar circuit topologies may be used at a wide range of power levels but the size and ratings of the components will have to change. Power ranges of electroactive polymer generators can go from 10 watts up to 100 kilowatts (or perhaps larger). As the power levels increase, the complexity of thermal management becomes an issue and needs to be seriously addressed (this is true for all methods of power generation).

### The Conservation of Charge Energy Conversion Model

As previously discussed in connection with FIGS. 3A-3B and 4A-4F, there are three mechanical to electrical energy conversion processes that are instructive to understanding the basics of electroactive polymer (dielectric elastomer) generators. These three cases all involve a simple four step process. The first step starts with a relaxed dielectric elastomer and uses mechanical energy to stretch the elastomer to some stretched state. The second step is to add electrical charge to the electroactive polymer electrodes. The third step is to mechanically relax the elastomer thereby converting the mechanical elastic energy into electrostatic energy and the fourth step is to remove the electrical energy from the electroactive generator thus “harvesting” electrical energy from the mechanical to electrical conversion.

During the second and third steps, the designer can choose between constant charge, constant electric field or constant voltage. Each of these methods requires different control circuit topologies. One of the simpler topologies to implement is the constant charge method and its cycle will be described in detail below.

For this analysis, a fixed stroke and fixed frequency system will be considered. Although variable stroke and variable frequency systems are not described, such systems are within the scope of the present disclosure. In addition, some typical values of parameters will be used to demonstrate practical electroactive polymer generator cycles. For example, an electroactive polymer generator one meter by one meter and one hundred microns thick in the relaxed state will be considered in the analysis and fully compliant and conducting electrodes will be assumed. Using the following set of parameters (ε₀=8.854 pF/m, εᵣ=5.0, μ₁=0.3 MPa, α₁=2, λₘₐₓ=2.0 and Vₘₐₓ=5 kV), a typical cycle may be constructed. The analysis will be presented in graphical form on energy versus stretch plane. This illustrative approach enables visualization of the concept of energy balance.

During the first portion of the cycle, the electroactive generator is stretched from 1 to λₘₐₓ, storing elastic energy in the electroactive polymer film. Next, an electrical charge (V_{seed}) is applied to the electroactive generator. Its voltage value depends on the maximum stretch as follows: V_{seed}=Vₘₐₓ/(λₘₐₓ)² (note: this value only applies to the shear mode analysis). As electrical energy is applied, it is added to the elastic energy stored in the electroactive polymer film. At this point the electrical charge seed source is disconnected from the generator and no charge is allowed to enter or leave the generator electrodes (hence the constant charge cycle). The electroactive generator is then allowed to relax back to the equilibrium condition converting the elastic energy into electrical energy. Finally, the electrical energy is removed from the generator and the cycle would be repeated again.

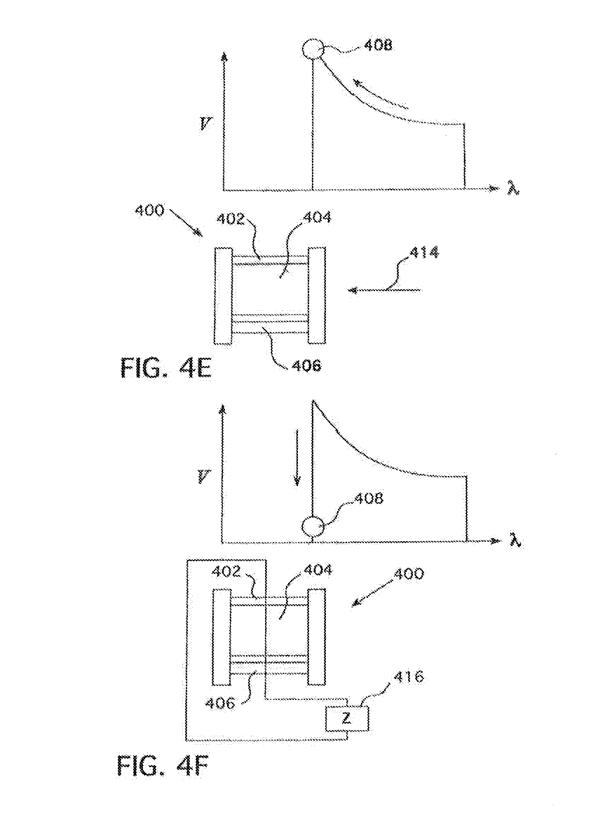

FIG. 6 is a graphical representation 1000 of energy versus stretch ratio of a constant charge cycle in an electroactive polymer generator. The vertical axis corresponds to Energy (Joules) and the horizontal axis corresponds to Stretch Ratio. The detailed description of the process is aided by the curves presented in FIG. 6. The elastic energy has already been presented in equation (17) (this is Step 1 moving from point A to point B). An external mechanical source is used to stretch the elastic generator storing elastic energy in the dielectric elastomer film. An electrical charge is added based on the seed voltage defined in the previous paragraph (this is Step 2 moving from point B to point C). At this point, the external mechanical source will start relaxing the dielectric elastomer to return it back to the relaxed position. If no electrical charge is applied on the generator then all of the energy the external mechanical source put into the generator would be returned back to the external mechanical source. With electrical charge on the generator, some of the elastic energy is converted into electrical energy and some is returned back to the external mechanical source. During Step 3, the electroactive polymer generator will return back to the equilibrium position D (where the system energy reaches a minimum). The electrical energy may now be removed for an overall electrical energy gain in the system (Step 4, point D to point A).

This basic constant charge cycle energy converter is the basis for the energy density calculation. This analysis has not included system losses and determines the energy per cycle under ideal conditions. Also, it should be noted that the large elastic energy that must be applied into the dielectric elastomer prior to adding any electrical seed energy should be considered carefully. In this example, the ratio of mechanical elastic energy to electrical energy is approximately 10:1 and has a significant system effect. If the modulus of the dielectric material is selected to be ten times greater, the ratio of elastic to electrical energy becomes 100 fold. This results in a very lopsided system and should be avoided. Such a large ratio presents significant cost, since mechanical structures (tethers, frames, etc.) must be built to handle this mechanical energy.

### Losses Due to Leakage Currents in the Dielectric

Referring back to the constant charge cycle described in reference to FIG. 6, it is assumed that no charge enters or leaves the electroactive polymer generator. If charge is allowed to move from one electrode to the other through the dielectric material, the constant charge cycle is no longer valid and the transfer of charge results in a significant energy loss. If this loss is too high, the electroactive polymer generator does not produce electrical energy and merely heats up the dielectric material. The undesired transfer of charge from one electrode to the other during a generation cycle is typically referred to as leakage current. The overall system sensitivity to leakage current depends on a number of different parameters. One of the more important parameters is cycle time and higher leakage current may be tolerated at higher mechanical frequencies.

Electroactive polymer generators (e.g., EAP generators or dielectric elastomer [DP] generators) may have a variety of operational configurations. In one embodiment, the control electronics account for these configurations. From the mechanical input power perspective, the input can range from fixed-stroke, fixed-frequency (example hydro river flow) to variable-stroke, variable-frequency (wave energy). There are also different conversion cycles, constant-charge, constant-field and constant-voltage (and subsets of these by not operating at maximum energy per cycle). Each application will have an optimum set of control requirements. Some example applications are:

River Source with No Seasonal Changes and Tied to the Grid.

Here the goal is to produce the most amount of power continuously and have the utility company pay you for the power produced. The flow to mechanical power may be a Pelton wheel or other similar efficient converter (assuming the river head is sufficient (low river head sources require a different type of converter). In one embodiment, the electroactive polymer generator would be designed to handle the continuous power of the source and constantly drive power into the grid (considered an infinite load for this case). Here the system design would be fixed-frequency and fixed-stroke giving the simplest control needed. The control system would operate at maximum power and only shut down in the event of a fault (either internal generator fault or external system fault i.e. water source became clogged with debris, utility grid was not functioning due to a lightning strike, etc.).

Wave Source Tied to an Energy Storage Device (Possibly Combined with Solar and Wind and Backup Diesel Generator), for Example, for Powering a Remote Fishing Vacation Resort.

Here the input mechanical power varies both in frequency and stroke. The load varies from minimum to maximum. In this case, the control system must adapt to the complex set of source and load requirements and optimize accordingly. In addition, fault conditions and excessive conditions must be considered and controlled, for example, if a storm produces waves in excess of the design maximums, the system would need to shut down in the safest configuration.

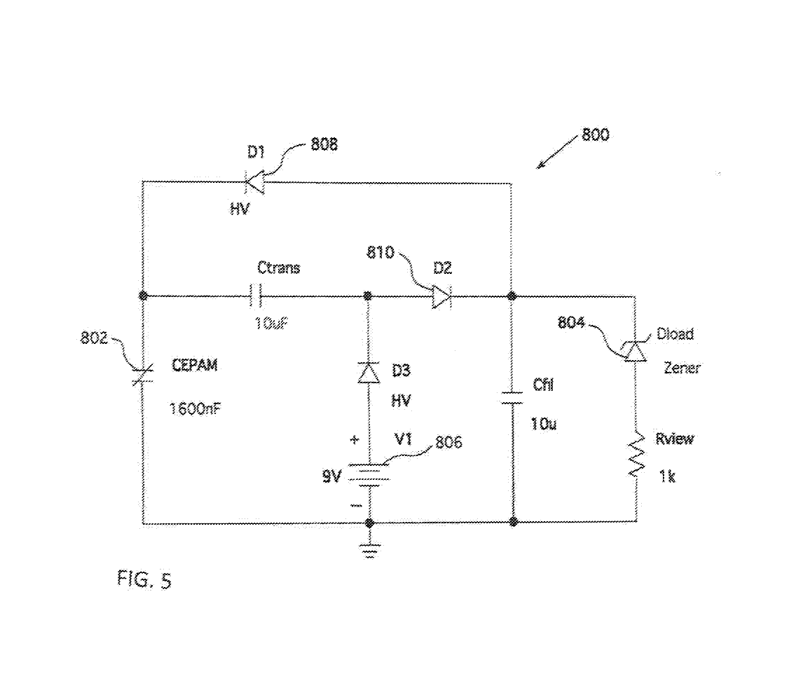

FIG. 7 is a block diagram of one embodiment of electroactive polymer generator energy harvesting control system 1800 utilizing microcontroller electronics 1802. In one embodiment, the control system 1800 optimizes and maximizes the performance of the electroactive polymer generators 1804 over a wide variety of operating conditions. The control system 1800 also may be employed to control electroactive polymer type damper systems, for example. In one embodiment, the control system 1800 maximizes the energy density of the electroactive polymer generator 1804. Complex control can improve the energy density of the electroactive polymer generator 1804 over an order of magnitude. The high efficiency energy transfer circuit controls a complex process of input output control variables to maximize the performance of the electroactive polymer generator 1804.

In one embodiment, an electroactive polymer generator 1804 uses mechanical input power and converts it into electrical output power. In one general embodiment, a basic electroactive polymer generator cycle comprises straining the electroactive polymer element of the generator 1804 thereby converting mechanical input into elastic strain energy, adding a small amount of electrical charge to “seed” the generator, relaxing the elastic strain converting the mechanical energy into electrical energy, and finally completing the cycle by removing the electrical energy. The mechanical input power to an electroactive polymer generator 1804 may range from fixed stroke, fixed frequency (water turbine, for example) to variable stroke, variable frequency (wave power, for example). The optimum cycle in each of the cases may be consistent (as in the water turbine case) or continuously changing (as in the wave power case). To adapt to these changes, the electroactive polymer generator control system evaluates input variables and modifies output control to optimize performance. The minimum input variables for the control system are generator strain and generator voltage. The minimum output control variables are generator charge rate and generator discharge rate. The control system uses these control variables and a predefined set of rules to optimize the performance of the electroactive polymer generator.

In the embodiment illustrated in FIG. 7, the control system 1800 comprises a controller 1802, which may comprise a microprocessor or microcontroller circuit. The controller 1802 is coupled to a charge controller 1806, a discharge controller 1801, and an energy storage element 1808 to control the charge rate and the discharge rate of the generator 1804. Generator feedback variables from a voltage monitor 1812 and a strain monitor 1814 are provided to the controller 1802.

In one embodiment, the charge controller 1806 is a high-voltage, high-power circuit suitable for charging a capacitance with a defined amount of charge (and hence energy). Two suitable topologies are the energy regulated charge circuit (as described in U.S. Pat. No. 6,359,420, which is incorporated herein by reference) or a constant current converter (flyback, forward, etc.). Because most electroactive polymer generators will have to trade off electrode resistance for cost and performance, it is expected that the equivalent series resistance of electroactive polymer generator 1804 will be relatively high. To minimize ohmic heating losses during charge (and discharge) the lowest amount of current for the longest time should be used (for a given amount of charge). The charge controller 1806 removes energy from the energy storage element 1808 and transfers it to the dielectric elastomer film of the electroactive polymer generator 1804 at the maximum strain of a cycle. Depending on the type of overall system, either the charge, the energy or the voltage is controlled (possibly combinations in complex systems).

In one embodiment, the configuration of the energy storage element 1808 will depend on the requirements of the control system 1800. It can be a capacitor bank (utility grid tie cases, for example) or a battery bank (off grid remote sites) or some combination. The main purpose of the energy storage element 1808 is to provide the initial seed electrical energy to charge the electroactive polymer generator 1804 at the start of each mechanical cycle.

Similar to the charge controller 1806, in one embodiment, the discharge controller 1810 is responsible for removing electrical energy from the electroactive polymer generator 1804 when the mechanical cycle has reached the minimum strain. In one embodiment, a flyback converter may be the most versatile because it can be controlled for all three types of conversion cycles (constant charge, constant voltage, and constant field). Other converter topologies may also be used. In most cases, it is desirable to have zero voltage (and zero charge) on the electroactive polymer generator 1804 during the stretching phase of the mechanical cycle to maximize the amount of mechanical energy put into the elastomer. The control system 1800 electronics determine when the discharge controller 1810 removes the energy from the electroactive polymer generator 1804.

In one embodiment, the voltage monitor 1812 is a very high impedance voltage divider used to determine the voltage on the electroactive polymer generator 1804. Bandwidth should be at least DC to 1 kHz and impedance should be high to keep losses below 1% of the typical conversion cycle, preferably less than 0.1%.

In one embodiment, the strain monitor 1814, whether fixed stroke or variable stroke, provides the strain condition of the electroactive polymer generator 1804 to the controller 1802. For fixed stroke systems this can easily be a shaft encoder but for variable stroke systems this may need to be a small section within the electroactive polymer generator 1804 used to monitor capacitance with the assumption that the small section represents the entire electroactive polymer generator 1804 strain. In simple systems the maximum strain would initiate the electrical charge cycle of the system and the minimum strain would initiate the electrical discharge cycle of the system. For variable stroke systems, the strain monitor 1814 can be used to determine when to start conversion cycles and when not to. For example, if the waves are not large enough and the electroactive polymer generator 1804 may is only straining 10-20%, the control system 1800 would decide not to do anything, later, once a 50% strain might be occurring, the controller 1802 starts up the conversion process.

As discussed above, electroactive polymer based energy harvesting generators may have high electrode resistance unlike conventional generators that employ highly conductive electrodes (or conductors) to minimize loss. For example, rotary electromagnetic generators use copper or aluminum wire for conductors because there is no need for a compliant conductor. The high electrode resistance of electroactive polymer generators is typically due to the additional electrode requirement of mechanical compliance. The electrode must be electrically conductive while simultaneously being compliant, and therefore, establishes an electrode design tradeoff between electrical conductivity and mechanical compliance. A highly conductive electrode (silver, for example) is very stiff and does not allow much mechanical movement. Less conductive electrodes (printed conductive inks, for example), on the other hand, are compliant and allow mechanical movement but are resistive and result in electrical losses when trying to charge or discharge an electroactive polymer generator.

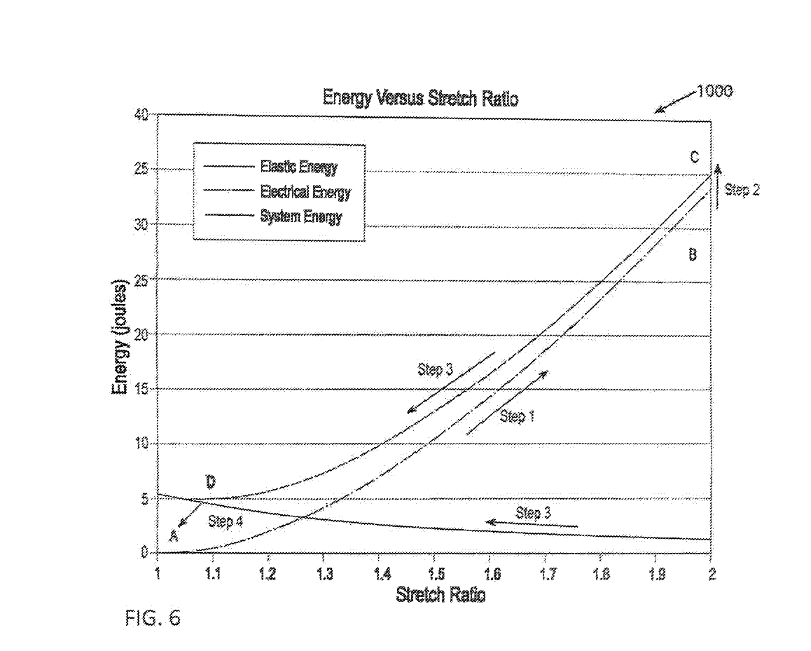

The simplified electronic circuit described in connection with FIG. 8, minimizes electrode losses by operating at low electrode currents. Such simplified electroactive polymer generator electronics, though configured for high electrode resistance, do not optimize the full mechanical-to-electrical conversion capabilities and result in much lower specific energy densities compared to optimized converter electronics, which are typically 0.04-0.06 Joules per gram for simple electronics versus 0.4-0.6 joules per gram for complex electronics.

FIG. 8 is a block diagram of one embodiment of a high efficiency energy transfer circuit 1900 for an electroactive polymer generator 1904, In FIG. 8, the high efficiency energy transfer circuit 1900 comprises control electronics 1902 coupled to an electroactive polymer generator 1904 via charge converter electronics 1906 and discharge converter electronics 1908. Current control signals 1912 are used to control the charge converter electronics 1906 and the discharge converter electronics 1908. Strain measurement electronics 1910 are coupled to the electroactive polymer generator 1904 and provide signals to the control electronics 1902. One advantage of such configuration is that electrical losses in the electroactive polymer generator 1904 are controlled and thus maximizing the overall conversion efficiency and performance.

In one embodiment, the electroactive polymer generator 1904 described herein employs controlled charge transfer to minimize electrode losses when either charging or discharging the generator 1904. In various embodiments, several methods of controlling charge transfer may be implemented. For example, synchronous parallel converters may be employed for charging in the charge converter electronics 1906 and continuous buck converters may be employed for discharging in the discharge converter electronics 1908. In one embodiment, the electronics and logic in the charge and discharge converter electronics 1906, 1908 are employed to limit the charge or discharge current to a level that reduces electrode losses to acceptable levels. This method provides an unexpected change of electrode resistance and limits its impact on the operating conditions of the electrical system. Both the capacitance of the generator 1904 and the equivalent electrode resistance of the generator 1904 vary with mechanical strain. To control the electrical losses during charging and discharging of the electroactive polymer generator 1904 the current is limited according to the following criteria:

$${I}_{MA X} = \frac{Δ V \times \% LOSS}{2 \times {R}_{ELECTRODE} ( strain )} \qquad ( 1 )$$

In accordance with one embodiment, electroactive polymer generators with high electrode resistance charge and discharge currents are controlled dependent on electrode resistances or excessive losses will result in poor overall generator efficiencies.

### Multi-Phase Balanced Electroactive Polymer Generator

Having described several embodiments of electroactive polymer generators and components thereof in a general manner, the present disclosure now turns to one embodiment of an electroactive polymer generator with a mechanical-to-electrical conversion efficiency that is greater than approximately 30%. In some embodiments, efficiencies greater than approximately 80% can be achieved using the techniques according to the various embodiments. For example, in one embodiment, mechanical-to-electrical reactive power efficiency can exceed 80% by configuring single elements of electroactive generators in multiple arrays. Such configurations of electroactive polymer generators may be referred to as, for example, multi-phase generators. Although the basic concept of multi-phase (poly-phase) power conversion is the basis for modern three-phase electrical power distribution systems, the concept has not been applied to electroactive polymer generators as described herein below. Although electroactive polymer generators have been described, there has been little disclosure of poly-phase electroactive polymer generators. In particular, optimized electroactive polymer generators have a minimum requirement of six phases because electrical power is generated only on one half cycle, but not in both directions like electromagnetic generators. Hence, the minimum optimum number of phases for electromagnetic generators is three and the minimum optimum number of phases for electroactive polymer generators is six. The embodiments, however, are not limited in this context and generators with two or more phases, including generators with more than six phases, are contemplated to be within the scope of this disclosure.

### Balance Multi-Phase Generator for Dielectric Elastomer Generators

In the dielectric elastomer generators described herein, elastomer films are alternately stretched and relaxed as part of a work cycle that convert mechanical power to electrical power. The mechanical power required to stretch and relax the elastomer film may be large compared to the power converted to electrical energy. In one embodiment, the peak mechanical energy stored in a film is typically about ten times larger than the energy converted to electricity. In one embodiment, the mechanical to electrical conversion efficiency is increased through a balanced multi-phase generator in which reactive mechanical energy is distributed among elastic elements, each at a different point in the work cycle, such that the total passive strain energy stored in the system is constant. In a balanced multi-phase generator, the system does not have a preferred rest position, and therefore does not require a heavy fly wheel or proof mass for smooth operation.

In one embodiment, a balanced multi-phase generator may comprise a transmission coupling mechanism to transform rotary motion into reciprocating motion that alternatively stretches and relaxes a plurality of transducers, with each transducer comprising a dielectric elastomer element. The plurality of transducers may be evenly distributed around a work cycle of the transmission coupling mechanism. In one embodiment, the plurality of transducers may comprise a first transducer and a second transducer located at opposite points in the work cycle. In another embodiment, the plurality of transducers may comprise six dielectric elements, each element being located at evenly spaced points in the work cycle. Those skilled in the art will recognize that any number of evenly spaced elements may be used. Although any number of evenly spaced dielectric elements may be used, optimized electroactive polymer generators have a minimum requirement of six phases because electrical power is generated only by one half cycle, but not in both directions like electromagnetic generators. Hence, the minimum optimum number of phases for electroactive polymer generators is six. The embodiments, however, are not limited in this context and generators with two or more phases are contemplated to be within the scope of this disclosure.

In one embodiment, a transmission coupling mechanism is configured to couple to the mechanical energy source and operatively attached to the plurality of transducers. The transmission coupling mechanism may cyclically strain and relax the plurality of transducers in response to the mechanical energy source acting on the transmission coupling mechanism. The transmission coupling mechanism may comprise a work cycle, with the plurality of transducers being evenly distributed about the transmission coupling mechanism's work cycle. For example, if the plurality of transducers comprises a first transducer and a second transducer, the first and second transducers may be configured at opposite points in the work cycle. As another example, if the plurality of transducers comprises six transducers, the six transducers may be evenly distributed about the work cycle at increments of sixty-degrees. Those skilled in the art will recognize that an even distribution of any number of transducers may be used.

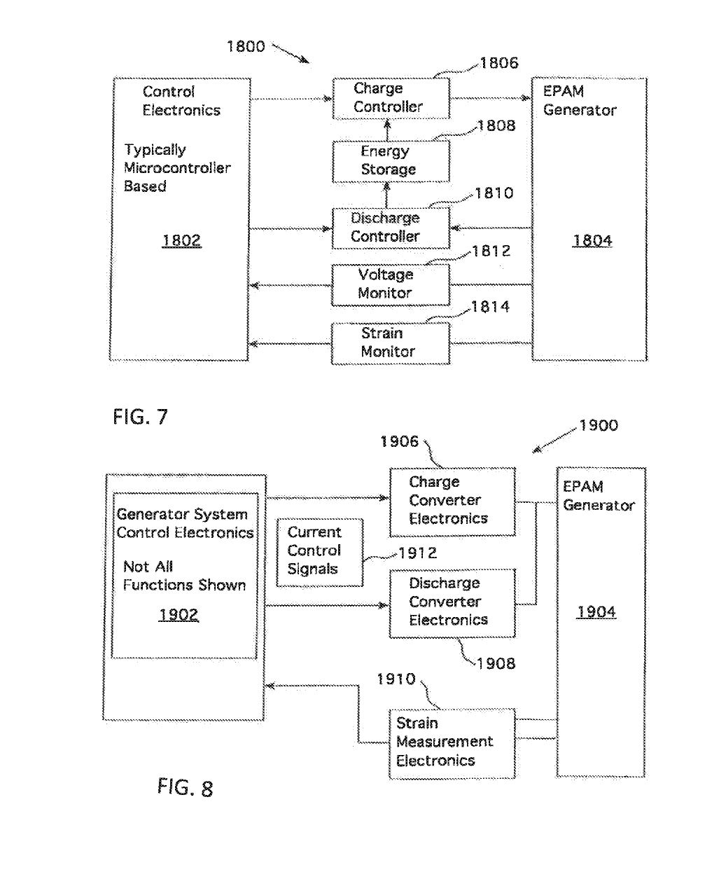

FIGS. 9-11 illustrate one embodiment of a balanced multi-phase generator 2500. The balanced multi-phase generator 2500 comprises first and second struts 2508a, 2508b. The first and second struts define first and second bearings, 2514a, 2514b. A shaft 2510 extends longitudinally through the first and second bearings and comprises a mechanical interface 2511 at a first end. A first swashplate 2514 and a second swashplate 2516 are operatively mounted to the shaft 2510. A first pair of hangers 2538a and a second pair of hangers 2539b are operatively coupled to joints formed on the first and second swashplates 2514, 2516 to support a plurality of generator elements (not shown) there between. The plurality of generator elements each include at least one linear electroactive polymer transducer such as the dielectric elastomer generator module 2520a. The module is made of stretchable electroactive polymer material, and specifically is made of dielectric elastomer, and converts mechanical work into electrical charge when it is stretched, seeded with a base voltage, relaxed, and discharged, as discussed above. The first and second swashplates 2514, 2516 comprise a disk attached to the shaft 2510 at an oblique angle. The first and second swashplates 2514, 2516 are mounted at opposite angles, such that the first and second swashplates 2514, 2516 form a counter-rotating pair. As the shaft 2510 rotates, the edges of the first and second swashplates 2514, 2516 describe a path that oscillates along the shaft's 2510 length, translating the rotational motion of the shaft 2510 into reciprocating motion of the first and second pair of hangers 2538, 2539.

As the mechanical work source applies a counter-rotational motion to the first and second swashplates 2514, 2516, the generator elements 2520a are stretched and relaxed over each cycle by the forces applied by the corresponding hanger plates 2538, 2539. Because each hanger plate is located at a different point on the first and second swashplates 2514, 2516, the generator elements 2520 are stretched and relaxed at alternative points in the work cycle.

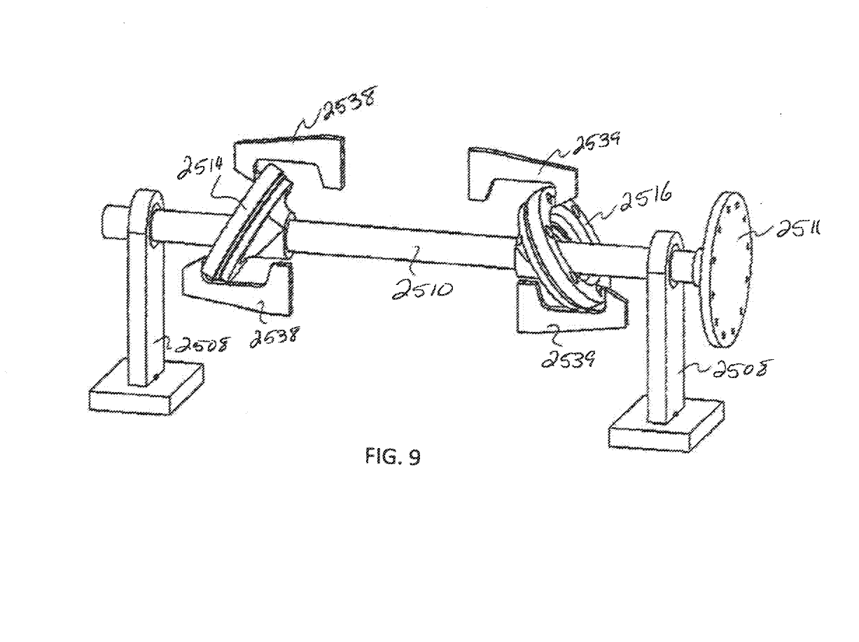

FIGS. 10A and 10B illustrate the balanced multi-phase generator 2500 with a first dielectric elastomer generator module 2520a and a second dielectric elastomer generator module 2520b at opposite points in a work cycle. The swashplates rotate at opposite, opposed angles to alternatively stretch and relax the first and second dielectric elastomer elements 2520a, 2520b out-of-phase by one half revolution. FIG. 10A shows the first and second dielectric elastomer elements 2520a, 2520b at a first point in the work cycle. The first dielectric elastomer generator module 2520a is at a minimum strain, or a relaxed, state in the work cycle. The second dielectric elastomer generator module 2520b is at a maximum strain state in the work cycle. The shaft 2510 is rotated by the mechanical energy through mechanical interface 2511, causing the first and second swashplates 2514, 2516 to rotate and the first and second dielectric elastomer elements 2520a, 2520b to cyclically relax and stretch through the work cycle.

FIG. 10B illustrates the balanced multi-phase generator 2500 at a second point in the work cycle. The first and second swashplates 2514, 2516 have been rotated 180 degrees. The first dielectric elastomer generator module 2520a is in the maximum strain state in the work cycle. The second dielectric elastomer generator module 2520b has been relaxed to the minimum strain state in the work cycle. As will be appreciated by one skilled in the art, although the strain states of the first and second dielectric elastomer elements 2520a, 2520b have been reversed, the total passive strain in the system is kept constant.

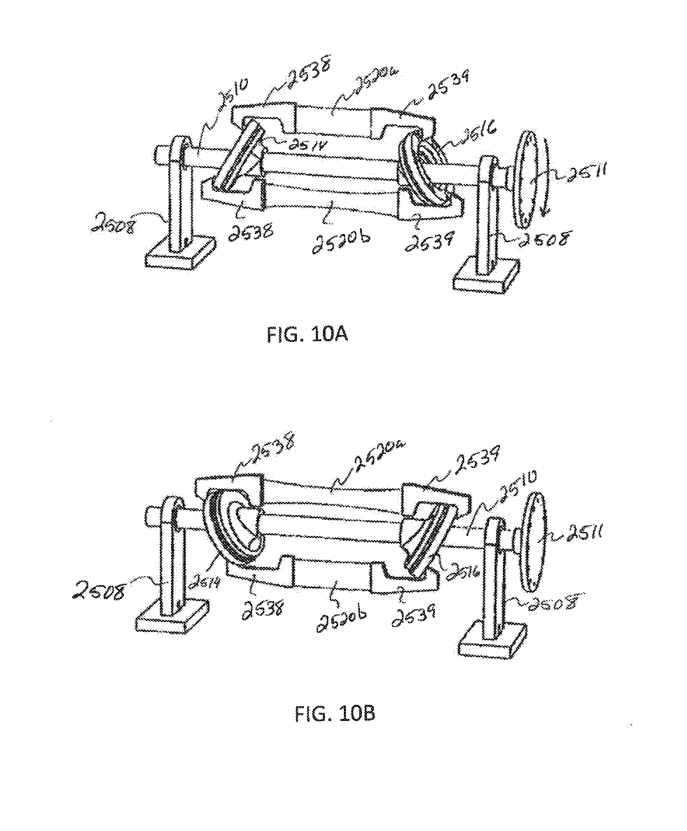

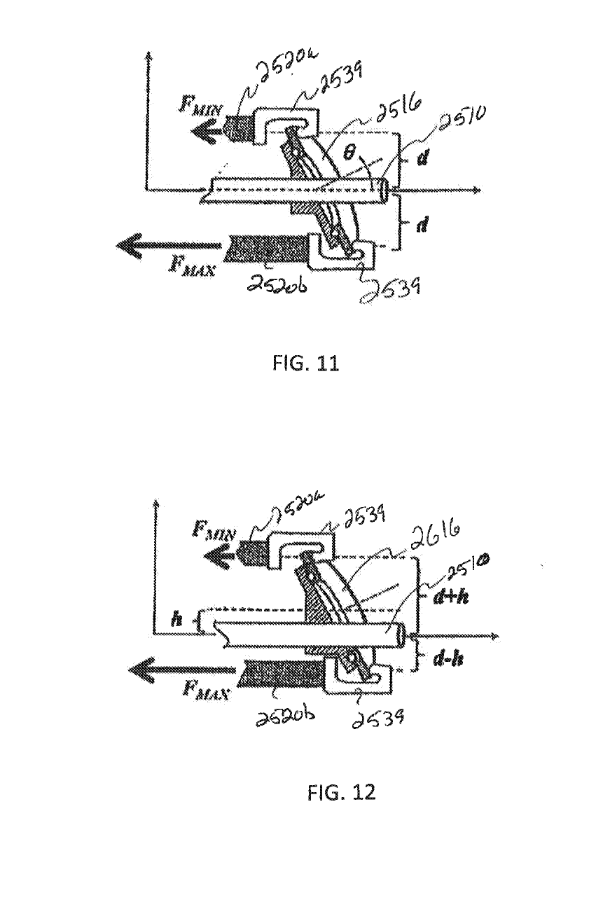

FIGS. 11 and 12 illustrate free body diagrams of two embodiments of the balanced multi-phase generator 2500. FIG. 11 illustrates one embodiment of a basic arrangement of the shaft 2510 and a swashplate 2516. In the basic arrangement, the second dielectric elastomer generator module 2520b is in the maximum strain state and exerts a greater bending moment 2613 on the shaft 2510 than the bending moment 2615 exerted by the first dielectric elastomer generator module 2520a which is in the relaxed state of the work cycle. Both the bending moment 2613 of the first dielectric elastomer generator module 2520a and the bending moment 2615 of the second dielectric elastomer generator module 2520b act through the same moment arm d, which is determined by the swashplate angle and radius. Therefore, the dielectric elastomer element in a maximum strain state, in this case the second dielectric elastomer generator module 2520b, places a greater rotation force on the shaft than the dielectric elastomer element in the relaxed state.

FIG. 12 illustrates one embodiment of the shaft 2510 and an off-set swashplate 2616. The off-set swashplate 2616 has an off-set of h from the shaft 2510. The first dielectric elastomer generator module 2520a has a bending moment equal to d+h. The second dielectric elastomer generator module 2520b has a bending moment equal to d−h. The off-set h balances the moments since the greater force, Fₘₐₓ generated by the dielectric elastomer element in the maximum strain state, here the second dielectric elastomer generator module 2520b, has the smaller moment. As the shaft 2510 rotates, the off-set swashplate 2616 rotates eccentrically around the shaft 2510, causing the off-set h to maintain an off-set in the direction of Fₘₐₓ. By off-setting the swashplate 2616, the total rotational forces exerted on the shaft 2510 can be reduced.

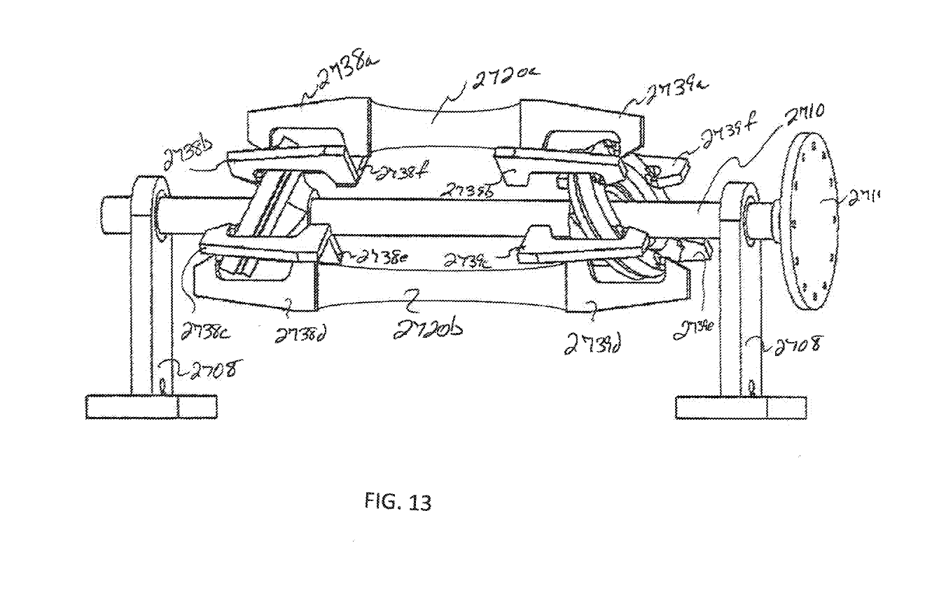

FIG. 13 illustrates one embodiment of a balanced multi-phase generator 2700 comprising six transducer elements. The balanced multi-phase generator 2700 comprises a first set of hanger plates 2738a-f and a second set of hanger plates 2739a-f. The first and second sets of hanger plates 2738a-f, 2739a-f are configured to support transducer elements therebetween. A first transducer element 2720a and a second transducer element 2720b are shown. The other four transducer elements have been omitted for clarity. The transducer elements comprise a dielectric elastomer module comprising stretchable electroactive polymer material comprising at least one dielectric elastomer film layer disposed between at least first and second electrodes. The first set of hanger plates 2738a-f are supported in a plurality of joints formed on a first swashplate 2714. The second set of hanger plates 2739a-f are supported in a plurality of joints formed on the second swashplate 2716. In various embodiments, the plurality of joints may comprise ball joints, universal joints, or any other suitable joint. The first and second swashplates are located on a shaft 2510 at opposing angles, e.g., when the first swashplate is offset from the vertical axis by 30°, the second swashplate is offset from the vertical axis by −30°. The opposed angles of the swashplates cause the transducers to alternatively stretch and relax as the shaft 2510 rotates.

In one embodiment, the work cycle of the first and second swashplates 2714, 2716 may comprise one complete revolution (360°) of the swashplate. Each of the six transducers are attached to a hanger plate form the first set 2738a-f and a hanger plate from the second set 2739a-f. For example, the first transducer 2720a may be attached to a first hanger plate 2738a and a second hanger plate 2739a. The hanger plates 2738a-f, 2739a-f, and the transducers supported there between, are located at evenly spaced points in the work cycles of the first and second swashplates. For example, the first transducer 2720a, the first hanger plate 2738a and the second hanger plate 2739a may be located at a designated point of 0° on the first and second swashplates 2714, 2716. The second transducer, and the associated hanger plates, may then be located at 60° on the work cycle, the third transducer located at 120°, the fourth transducer located at 180°, the fifth transducer located at 240°, and the sixth transducer located at 300°. As the shaft 2510 rotates, the first and second swashplates 2714, 2716 transition through the work cycle in unison, alternatively stretching and relaxing each of the six transducers. In the illustrated embodiment, each transducer has a paired transducer located at an opposite point in the work cycle. For example, if a first transducer is in a maximum strain state, a second transducer, located 180° from the first transducer, will be in a minimum strain state. As the first transducer transitions to a minimum strain state, the second transducer will transition to a maximum strain state, resulting in zero net force gain within the system.

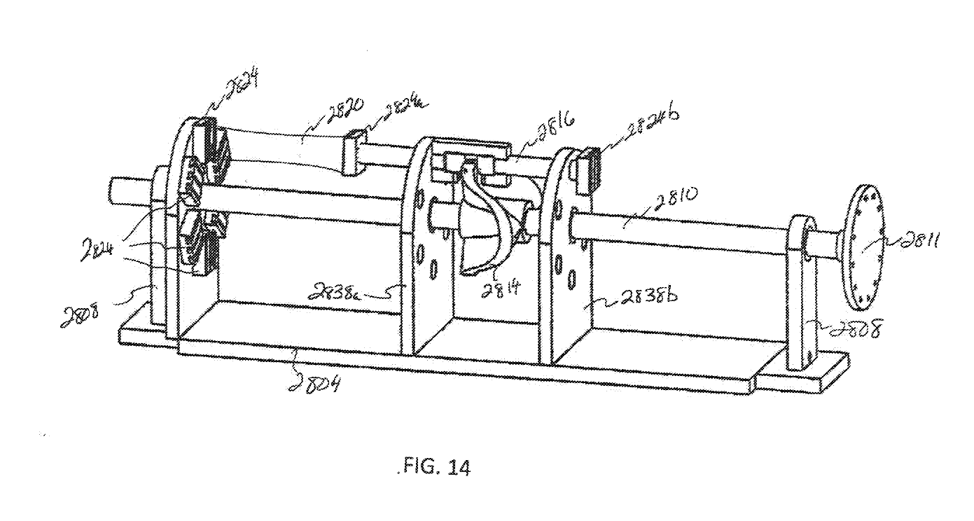

FIG. 14 illustrates an embodiment of a balanced multi-phase generator 2800 comprising a sinusoidal cam 2814. The balanced multi-phase generator 2800 comprises a shaft 2810 having a transmission coupling mechanism comprising a sinusoidal cam 2814. The shaft 2810 is coupled to a mechanical energy source through a mechanical interface 2811. The mechanical energy source may be any suitable source of mechanical energy, such as, for example, water at rest or in motion, tides, waves, wind, solar, or geothermal, among others. The mechanical energy source causes the shaft 2810 to rotate. The sinusoidal cam 2814 is fixedly attached to the shaft, such that the sinusoidal cam 2814 rotates in unison with the shaft 2810. A cam shaft 2816 comprises a first end and a second end and is operatively coupled to the sinusoidal cam 2814. As the sinusoidal cam 2814 rotates due to the mechanical energy source, the sinusoidal cam reciprocates between a first cam plate 2838a and a second cam plate 2838b. The first and second cam plates 2838a, 2838b may be attached to a base 2804. Mounting elements, in the form of slotted blocks 2824a, 2824b, are fixedly attached to the first and second ends of the cam shaft 2816.

The balanced multi-phase generator 2800 may further comprise one or more mounting plates 2841. The mounting plates 2841 may be located at the ends of the base 2804 along the longitudinal axis and extend vertically from the base 2804. The mounting plates 2841 may have one or more mounting elements, such as, for example, slotted blocks 2824, mounted such that each slotted block 2824 is axially aligned with a mounting element 2824 of a cam shaft 2816. A transducer comprising a dielectric elastomer module may be fixedly attached to a slotted block 2824 located on a cam shaft 2816 and a slotted block 2825 located on a mounting plate 2841. As the sinusoidal gear rotates the cam shaft 2816 reciprocates between the first and second cam plates, 2838a, 2838b causing the dielectric elastomer module to alternatively stretch and relax. Attaching a dielectric elastomer generator module 2820 to either side of the cam shaft allows the shaft to operate two dielectric elastomer generator modules 2820 during one work cycle of the sinusoidal cam 2814. In one embodiment, the balanced multi-phase generator 2800 may comprise six cam shafts 2816, two mounting plates 2841, and twelve dielectric elastomer generator modules 2820 located between the cam shafts 2816 and the mounting plates 2841.

It is worthy to note that any reference to “one embodiment” or “an embodiment” means that a particular feature, structure, or characteristic described in connection with the embodiment is included in at least one embodiment. The appearances of the phrase “in one embodiment” or “in one aspect” in the specification are not necessarily all referring to the same embodiment.

It is worthy to note that some embodiments may be described using the expression “coupled” and “connected” along with their derivatives. These terms are not intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still co-operate or interact with each other.

It will be appreciated that those skilled in the art will be able to devise various arrangements which, although not explicitly described or shown herein, embody the principles of the present disclosure and are included within the scope thereof. Furthermore, all examples and conditional language recited herein are principally intended to aid the reader in understanding the principles described in the present disclosure and the concepts contributed to furthering the art, and are to be construed as being without limitation to such specifically recited examples and conditions. Moreover, all statements herein reciting principles, embodiments, and embodiments as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. The scope of the present disclosure, therefore, is not intended to be limited to the exemplary embodiments and embodiments shown and described herein. Rather, the scope of present disclosure is embodied by the appended claims.

The terms “a” and “an” and “the” and similar referents used in the context of the present disclosure (especially in the context of the following claims) are to be construed to cover both the singular and the plural, unless otherwise indicated herein or clearly contradicted by context. Recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (e.g., “such as,” “in the case,” “by way of example”) provided herein is intended merely to better illuminate the invention and does not pose a limitation on the scope of the invention otherwise claimed. No language in the specification should be construed as indicating any non-claimed element essential to the practice of the invention. It is further noted that the claims may be drafted to exclude any optional element. As such, this statement is intended to serve as antecedent basis for use of such exclusive terminology as solely, only and the like in connection with the recitation of claim elements, or use of a negative limitation.

Groupings of alternative elements or embodiments disclosed herein are not to be construed as limitations. Each group member may be referred to and claimed individually or in any combination with other members of the group or other elements found herein. It is anticipated that one or more members of a group may be included in, or deleted from, a group for reasons of convenience and/or patentability.

While certain features of the embodiments have been illustrated as described above, many modifications, substitutions, changes and equivalents will now occur to those skilled in the art. It is therefore to be understood that the appended claims are intended to cover all such modifications and changes as fall within the scope of the disclosed embodiments and appended claims.

What is claimed is:

1. A balanced multi-phase energy conversion apparatus configured to convert energy from a mechanical energy source into electrical energy, the energy conversion apparatus comprising:
a plurality of transducers, each of the plurality of transducers comprising a dielectric elastomer module comprising at least one dielectric elastomer film layer disposed between at least first and second electrodes; and
a transmission coupling mechanism configured to couple to the mechanical energy source and operatively attached to the plurality of transducers to cyclically strain and relax the plurality of transducers in response to the mechanical energy acting on the transmission coupling mechanism, the transmission coupling mechanism comprising a work cycle, wherein the plurality of transducers are at evenly distributed points in the work cycle such that a total passive strain energy is constant.

2. The balanced multi-phase energy conversion apparatus according to claim 1, wherein:
the plurality of transducers comprises a first transducer and a second transducer; and
wherein the first and second transducers are configured at opposite points in the work cycle.

3. The balanced multi-phase energy conversion apparatus according to claim 2, wherein:
the plurality of transducers comprise a third transducer, a fourth transducer, a fifth transducer and a sixth transducer; and
wherein the first, second, third, fourth, fifth, and sixth transducers are evenly distributed around the work cycle.

4. The balanced multi-phase energy conversion apparatus according to claim 3, wherein there is at least one additional pair of transducers evenly distributed around the work cycle with the first six transducers.

5. The balanced multi-phase energy conversion apparatus according to any one of claims 1 to 3, wherein the transmission coupling mechanism transforms rotary motion into reciprocal motion.

6. The balanced multi-phase energy conversion apparatus according to claim 5, wherein the transmission coupling mechanism comprises a pair of opposed counter-rotating generator elements.

7. The balanced multi-phase energy conversion apparatus according to claim 6, wherein the transmission coupling comprises:
a shaft;
wherein the pair of opposed counter-rotating generator elements comprise a first swashplate and a second swashplate, the first and second swashplates defining one or more joints formed thereon, the first and second swashplates operatively coupled to the shaft.

8. The balanced multi-phase energy conversion apparatus according to claim 7, wherein the first and second swashplates are offset from the shaft axis.

9. The balanced multi-phase energy conversion apparatus according to claim 7, comprising:
a first hanger plate having a first end operatively coupled to a first joint in the first swashplate;
a second hanger plate having a first end operatively coupled to a first joint in the second swashplate;
wherein, the first and second hanger plates are coupled to the first transducer and operatively coupled to the first joints located on respective first and second swashplates;
a third hanger plate having a first end operatively coupled to a second joint in the first swashplate;
a fourth hanger plate having a first end operatively coupled to a second joint in the second swashplate; and
wherein, the third and fourth hanger plates are coupled to the second transducer and operatively coupled to the second joints located on respective first and second swashplates.

10. The balanced multi-phase energy conversion apparatus according to any one of claims 7 to 9, wherein the one or more joints comprise ball joints.

11. The balanced multi-phase energy conversion apparatus according to any one of claims 7 to 9, wherein the one or more joints comprise universal joints.

12. The balanced multi-phase energy conversion apparatus according to claim 5, wherein the transmission coupling mechanism comprises a sinusoidal cam.

13. The balanced multi-phase energy conversion apparatus according to claim 12, the sinusoidal cam comprising:
a first shaft plate and a second shaft plate, the first shaft plate comprising a first plurality of holes, the second shaft plate comprising a second plurality of holes;
at least one cam shaft comprising a first end and a second end, the at least one cam shaft being operatively located between the first and second shaft plates, wherein the at least one cam shaft extends through one of the first plurality of holes and one of the second plurality of holes.

14. The balanced multi-phase energy conversion apparatus according to claim 13, comprising:
a first mounting element located on the first end of the at least one cam shaft; and
a first mounting block, wherein the first transducer is coupled between the first mounting element and the first mounting block.

15. The balanced multi-phase energy conversion apparatus according to claim 14, comprising:
a second mounting element located on the second end of the at least one cam shaft;
a second mounting block, wherein the second transducer is coupled between the second mounting element and the second mounting block.

16. The balanced multi-phase energy conversion apparatus according to any one of claims 1 to 15 comprising:
a conditioning circuit coupled to the at least first and second electrodes and configured to apply an electric charge to the dielectric elastomer film when the dielectric elastomer film is in a strained state, to disconnect from the dielectric elastomer film when the dielectric elastomer film transitions from the strained state to a relaxed state, and to remove electrical charge from the dielectric elastomer film when the dielectric elastomer film reaches a relaxed state.

17. The balanced multi-phase energy conversion apparatus according to any of claims 1 to 16, wherein the dielectric elastomer module comprises a plurality of dielectric elastomer film elements layered between a plurality of frame elements and a plurality of electrodes formed on each layer.

18. The balanced multi-phase energy conversion apparatus according to claim 17, comprising a bus electrode located on at least one of the frame elements to couple the conditioning circuit to the plurality of electrodes.

19. A method of generating balanced multi-phase energy from a mechanical energy source, the method comprising:
arranging a first dielectric elastomer film and a second dielectric elastomer film at opposite points in a work cycle;
alternately straining and relaxing the first and second dielectric elastomer films to a predetermined maximum strain of the work cycle using a mechanical energy source such that a total passive strain energy remains constant;
monitoring, by a strain controller, when the first or second dielectric elastomer film reaches the predetermined maximum strain of the work cycle;
transferring, by a charge controller, an electrical charge to the first and second dielectric elastomer film when the first and second dielectric elastomer films reach the maximum strain of the work cycle;
removing by the charge controller the electrical charge on the first and second dielectric elastomer when the first and second dielectric elastomer reaches a predetermined minimum strain of the work cycle.

20. The method according to claim 19, comprising:
removing, by the charge controller, the electrical charge from an energy storage element; and
transferring the electrical charge removed from the energy storage element to the first and second dielectric elastomer film when the first and second dielectric elastomer films reach the maximum strain of the work cycle.

21. The method according to claim 20, comprising:
determining at least one of a voltage or a strain condition on the first and second dielectric elastomer films by at least one of a voltage monitor or a strain monitor; and
providing at least one of the voltage or strain measurements to the controller.
